(19) United States
(12) Patent Application Publication
(10) Pub. No.: US 2019/0006842 A1
(43) Pub. Date: Jan. 3, 2019

(54) PROTECTION CIRCUIT

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Kentaro WATANABE, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 15/897,353

(22) Filed: Feb. 15, 2018

(30) Foreign Application Priority Data
Jun. 29, 2017 (JP) 2017-127992

(51) Int. Cl. H02H 9/04; H01L 27/02

(52) U.S. Cl. CPC H02H 9/046; H01L 27/0629; H01L 27/0266

(57) ABSTRACT

According to one embodiment, a first transistor includes a first terminal connected to a first pad supplied a first voltage, a second terminal and a back gate connected to a first node, and a gate connected to a second node. A second transistor includes a first terminal connected to the first node, a second terminal and a back gate connected to a second pad supplied a second voltage. A switch connects the second node to the first pad in case a first logic signal is input to a gate of the second transistor, and disconnects the second node from the first pad and connects the second node to the first node in case a second logic signal opposite to the first logic signal is input to the gate of the second transistor.

### CROSS REFERENCE TO RELATED APPLICATIONS

This application is based upon and claims the benefit of priority from Japanese Patent Application No. 2017-127992, filed Jun. 29, 2017, the entire contents of which are incorporated herein by reference.

### FIELD

Embodiments described herein relate generally to a power supply protection circuit.

### BACKGROUND

A known protection circuit protects circuits of a semiconductor device from a surge.

### BRIEF DESCRIPTION OF THE DRAWINGS

FIG. 1 is a block diagram for describing the configuration of a semiconductor device according to a first embodiment.

FIG. 2 is a circuit diagram for describing the configuration of a protection circuit of the semiconductor device according to the first embodiment.

FIG. 3 is a timing chart for describing the operation of the protection circuit of the semiconductor device according to the first embodiment.

FIG. 4 is a circuit diagram for describing the configuration of a protection circuit of a semiconductor device according to a comparative example.

FIG. 5 is a diagram for describing one example of advantages of the first embodiment.

FIG. 6 is a diagram for describing another example of advantages of the first embodiment.

FIG. 7 is a circuit diagram for describing the configuration of a protection circuit of a semiconductor device according to a first modification of the first embodiment.

FIG. 8 is a circuit diagram for describing the configuration of a protection circuit of a semiconductor device according to a second modification of the first embodiment.

FIG. 9 is a circuit diagram for describing the configuration of the protection circuit of the semiconductor device according to the second modification of the first embodiment.

FIG. 10 is a circuit diagram for describing the configuration of the protection circuit of the semiconductor device according to the second modification of the first embodiment.

FIG. 11 is a circuit diagram for describing the configuration of a protection circuit of a semiconductor device according to a third modification of the first embodiment.

FIG. 12 is a timing chart for describing the configuration of the protection circuit of the semiconductor device according to the third modification of the first embodiment.

FIG. 13 is a circuit diagram for describing the configuration of a protection circuit of a semiconductor device according to a second embodiment.

FIG. 14 is a timing chart for describing the operation of the protection circuit of the semiconductor device according to the second embodiment.

FIG. 15 is a circuit diagram for describing the configuration of a protection circuit of a semiconductor device according to a first modification of the second embodiment.

FIG. 16 is a circuit diagram for describing the configuration of a protection circuit of a semiconductor device according to a second modification of the second embodiment.

FIG. 17 is a circuit diagram for describing the configuration of the protection circuit of the semiconductor device according to the second modification of the second embodiment.

FIG. 18 is a circuit diagram for describing the configuration of the protection circuit of the semiconductor device according to the second modification of the second embodiment.

FIG. 19 is a circuit diagram for describing the configuration of a protection circuit of a semiconductor device according to a third modification of the second embodiment.

FIG. 20 is a timing chart for describing the configuration of the protection circuit of the semiconductor device according to the third modification of the second embodiment.

### DETAILED DESCRIPTION

In general, according to one embodiment, a protection circuit of a semiconductor device includes a first pad, second pad, a first transistor, second transistor, and a switch circuit. A first voltage is supplied to the first pad. A second voltage that is different from the first voltage is supplied to the second pad. The first transistor includes a first terminal that is electrically connected to the first pad, a second terminal and a back gate that are electrically connected to a first node, and a gate that is electrically connected to a second node. The second transistor includes a first terminal that is electrically connected to the first node, a second terminal and a back gate that are electrically connected to the second pad, and a gate. The switch circuit electrically connects the second node to the first pad in a case where a first logic signal is input to the gate of the second transistor, and electrically disconnects the second node from the first pad and electrically connects the second node to the first node in a case where a second logic signal whose logic level is opposite to a logic level of the first logic signal is input to the gate of the second transistor.

Hereinafter, embodiments will be described with reference to the drawings. In the following description, common reference numerals denote components having the same functions and configurations.

### 1. First Embodiment

A protection circuit according to a first embodiment is explained below.

### 1.1 Configuration

To begin with, the configuration of a semiconductor device including a protection circuit according to the first embodiment will be described.

### 1.1.1 Configuration of Semiconductor Device

FIG. 1 is a block diagram illustrating an example of the configuration of the semiconductor device according to the first embodiment. A semiconductor device 1 includes a semiconductor chip which executes a predetermined process in response to input signals from an external device (not shown), and outputs output signals.

The semiconductor device 1 communicates signals I/O with, for example, the external device. The I/O signals correspond to the substance of data transmitted or received by the semiconductor device 1 to or from the external device, and includes input signals and output signals.

Various voltages are supplied to a semiconductor device 1. The voltages to be supplied to the semiconductor device 1 include, for example, voltages VDD and VSS. The voltage VDD is a reference voltage to be used for driving the semiconductor device 1 and is, for example, 1.8V. The voltage VSS is a ground voltage and is lower than the voltage VDD. The voltage VSS is, for example, 0 V.

The semiconductor device 1 includes a pad group 11, an interface circuit 12, a protection circuit 13, and an internal circuit 14.

The pad group 11 includes pads P1 and P2 for voltage supply. The pads P1 and P2 are to provide the voltages VDD and VSS to the protection circuit 13, respectively. In the example of FIG. 1, although each of the pads P1 and P2 is illustrated as one functional block, they are not limited to this, and a plurality of blocks may be provided. When a plurality of pads for the pads P1 and P2 are provided in one chip, these pads for the pads P1 and P2 may be laid out in a distributed fashion at a plurality of locations within the chip.

The pad group 11 further includes, for example, a pad P3 for signal transmission/reception. The pad P3 is for forwarding inputs signal received from the external device, to the interface circuit 12. The pad P3 is also for outputting signals received from the interface circuit 12, as output signals, to the outside of the semiconductor device 10.

Upon reception of input signals as signals I/O from the pad P3, the interface circuit 12 forwards the input signals to the internal circuit 14. Also, upon reception of output signals from the internal circuit 14, the interface circuit 12 outputs the output signals to the outside via the pad P3.

The protection circuit 13 shares the voltage VDD with the interface circuit 12. For example, the protection circuit 13 has a function of providing the interface circuit 12 with a voltage VDD in which the effect of a surge is reduced, based on the voltages VDD and VSS, when the surge occurs in the voltage VDD. The details of the protection circuit 13 will be described later. If a plurality of pads for the pads P1 and P2 are provided, for example, a plurality of power supply protection circuits 13 are provided in a manner to correspond to the layout of these pads for the pads P1 and P2 within the chip.

The internal circuit 14 includes functions and configurations for executing certain processes of the semiconductor device 1. Upon receipt of a signal from the interface circuit 12, the internal circuit 14 executes a predetermined process and generates output signals as a result of the predetermined process.

### 1.1.2 Configuration of Protection Circuit

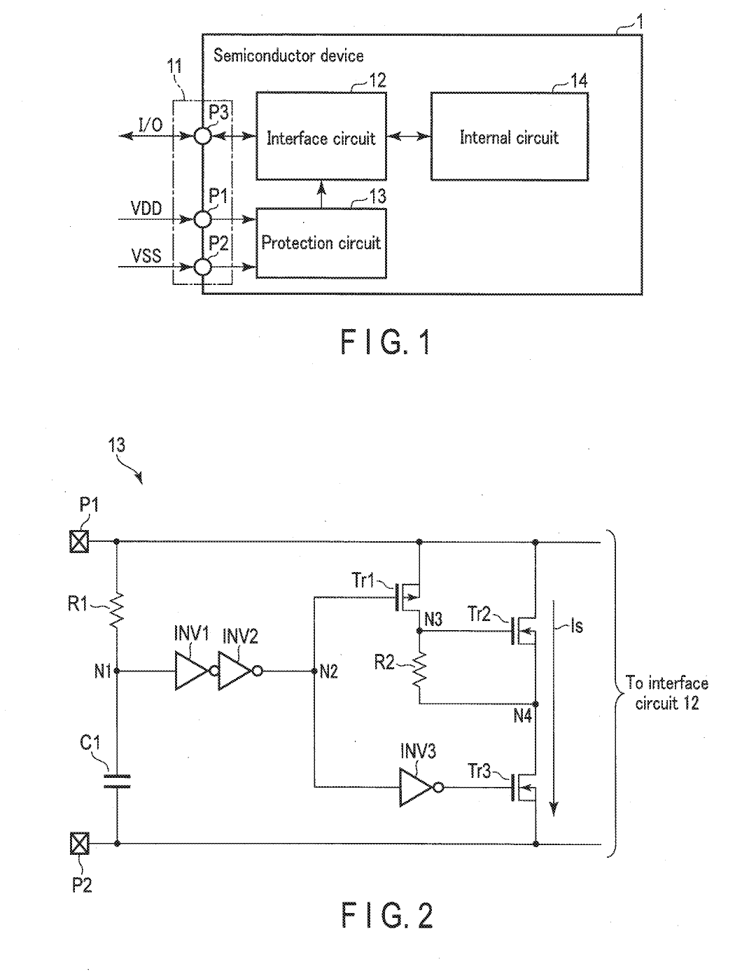

Next, the configuration of the protection circuit of the semiconductor device according to the first embodiment will be described with reference to FIG. 2.

As shown in FIG. 2, the protection circuit 13 includes transistors Tr1, Tr2, and Tr3, resistors R1 and R2, capacitor C1, and inverters INV1, INV2, and INV3. The transistor Tr1 is, for example, a metal oxide semiconductor (MOS) transistor having a p-channel polarity. The transistors Tr2 and Tr3 are, for example, a MOS transistor having an n-channel polarity. The transistors Tr1 to Tr3, the resistors R1 and R2, the capacitor C1, and the inverters INV1-INV3 can function as a resistance capacitor triggered (RCT) MOS circuit.

As described above, the voltages VDD and VSS are supplied to the protection circuit 13 via the pads P1 and P2, respectively.

The resistor R1 includes a first terminal connected to the pad P1, and a second terminal connected to a node N1. The capacitor C1 includes a first terminal connected to the node N1, and a second terminal connected to the pad P2. The resistor R1 and the capacitor C1 function as an RC timer which operates according to a time constant determined based on a resistance value of the resistor R1 and a capacitance of the capacitor C1. Specifically, the voltage of the node N1 follows voltage fluctuation of the pad P1 with a time delay based on the aforementioned time constant.

The inverters INV1 and INV2 are connected in series between the nodes N1 and N2. Specifically, the inverter INV1 includes an input terminal connected to the node N1, and an output terminal connected to an input terminal of the inverter INV2. The inverter INV2 includes an output terminal connected to the node N2.

The inverter INV3 includes an input terminal connected to the node N2, and an output terminal connected to a gate of the transistor Tr3.

The inverters INV1 to INV3 may be configured to output a signal of a value in accordance with a potential difference between the pads P1 and P2.

The transistor Tr1 includes a first terminal and a back gate both connected to the pad P1, a second terminal connected to the node N3, and a gate connected to N2. That is, the first terminal and the second terminal of the transistor Tr1 function as a source and a drain, respectively. The back gate is also referred to as a “body”.

The resistor R2 includes a first terminal connected to the node N3, and a second terminal connected to a node N4.

The transistor Tr2 includes a first terminal connected to the pad P1, a second terminal and a back gate both connected to the node N4, and a gate connected to the node N3. The transistor Tr3 includes a first terminal connected to the node N4, a second terminal and a back gate both connected to the pad P2, and a gate connected to the output terminal of the inverter INV3. That is, the first terminals of the transistors Tr2 and Tr3 function as a drain, and the second terminals of the transistors Tr2 and Tr3 function as a source.

Each of the transistors Tr2 and Tr3 has a function of causing an on-state current Is to follow from their first terminals to their second terminals by entering an ON state when a voltage of the pad P1 sharply rises, thereby mitigating the influence on the interface circuit 12 due to the sharp change of the voltage of the pad P1. It is preferable that the transistors Tr2 and Tr3 have approximately the same gate size. The gate size indicates, for example, a ratio of gate width W to gate length L (W/L). The gate sizes of the transistors Tr2 and Tr3 are greater than the gate size of the other transistor Tr1.

It is preferable that the transistors Tr1 to Tr3 are switched to the ON state or to the OFF state, for example, at a certain voltage (to be referred to as “voltage VT” for the purpose of convenience) between the voltage VDD and voltage VSS. It is more preferable that the voltage VT is set between the voltage VDD and the voltage VDD/2. The transistor Tr1 enters the ON state when a voltage that is lower than the voltage VT is applied to its gate, and enters the OFF state when a voltage higher than the voltage VT is applied to its gate. Besides, the transistors Tr2 and Tr3 enter the OFF state when a voltage lower than the voltage VT is applied to their gates, and enter the ON state when a voltage higher than the voltage VT is applied to their gates. In this manner, regarding a transistor with the p-channel polarity and a transistor with the n-channel polarity, it is preferable that when one of them is in the ON state, the other is in the OFF state, and when one of them is in the OFF state, the other is in the ON state.

In the description below, regarding voltages which are applied to the gates of the transistors Tr1 to Tr3, a logic level of a voltage lower than the voltage VT is referred to as the “L” level, and a logic level of a voltage higher than the voltage VT is referred to as the “H” level.

In a similar manner to the transistors Tr1 to Tr3, each of the inverters INV1 to INV3 may be configured so that a logic level of a signal that is output from the output terminal is switched, depending on whether a voltage that is input to the input terminal is lower or greater than the voltage VT. To be more specific, each of the inverters INV1 to INV3 outputs the “H” level from the output terminal when the “L” level is input to the input terminal, and outputs the “L” level from the output terminal when the “H” level is input to the input terminal. With this configuration, each of the inverters INV1 to INV3 functions as, for example, a signal control circuit which switches a logic level of a signal to be input to the gate of each of the transistors Tr1 and Tr3, depending on whether a voltage value of the node N1 exceeds the voltage VT or not.

### 1.2 Operation of Protection Circuit

Next, a description will be given of the operation of the protection circuit of the semiconductor device according to the first embodiment.

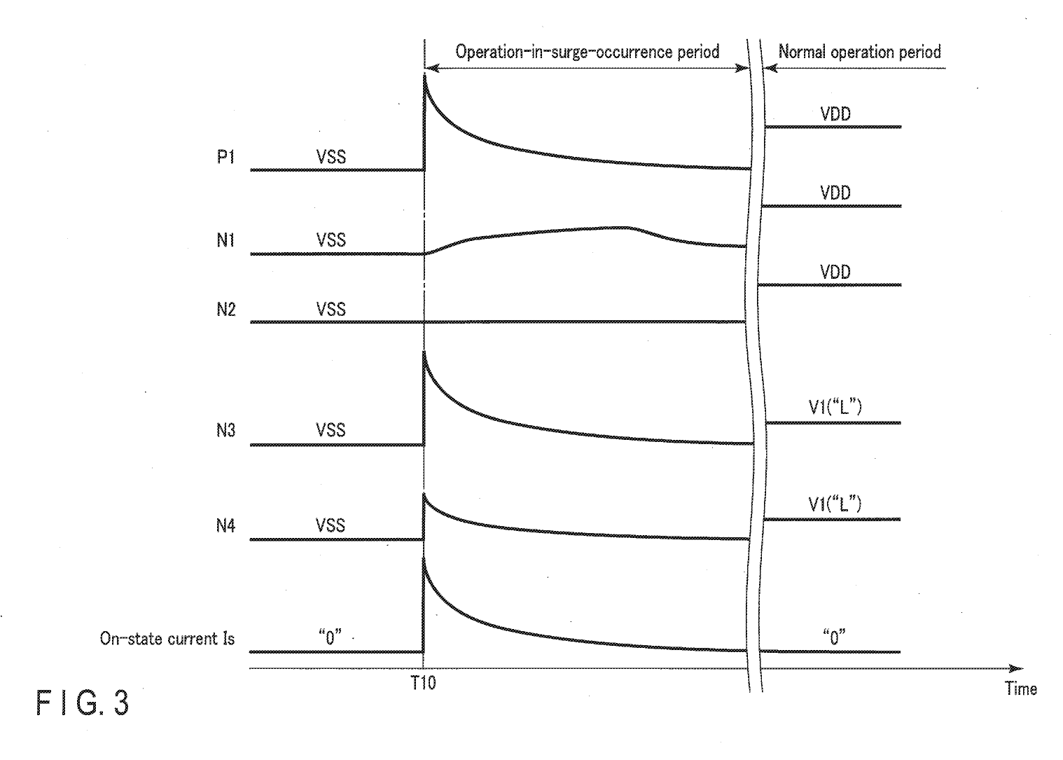

FIG. 3 is a timing chart for describing the operation of the protection circuit according to the first embodiment. FIG. 3 shows, as one example, the operation of the protection circuit 13 at the time that a surge occurs and the time that a power supply is normally supplied. FIG. 3 shows, in one example of occurrence of a surge, a case where the surge occurs in accordance with the human-body model (HBM). In the description below, an “operation-in-surge-occurrence period” refers to a period for which the protection circuit 13 operates at the time that a surge occurs, while a “normal operation period” refers to a period for which the protection circuit 13 operates at the time that a power supply normally supplies power.

As shown in FIG. 3, the voltage VDD is not supplied to the semiconductor device 1 until time T10. Thus, the pads P1 and P2 have, for example, the voltage VSS. The nodes N1, N2, N3, and N4 have the voltage VSS (“L” level). Then, the transistors Tr2 and Tr3 enter the OFF state, and the on-state current Is does not flow.

Occurrence of a surge at time T10 causes the voltage of the pad P1 to sharply rise, and then, the voltage of the pad P1 gradually approaches the voltage VSS. The voltage of the node N1 gradually increases, as an electric charge is accumulated in the capacitor C1 due to the surge. However, the voltage of the node N1 decreases again with a decrease in voltage of the pad P1. For this reason, the voltage of the node N1 remains at the “L” level during the operation-in-surge-occurrence period.

Thereby, the inverter INV1 outputs the “H” level. The “H” level output from the inverter INV1 is input to the inverter INV2. Then, the inverter INV2 outputs the “L” level to the node N2. Thus, the “L” level output from the inverter INV2 is input to the gate of the transistor Tr1 and to the input terminal of the inverter INV3.

The inverter INV3 outputs the “H” level upon input of the “L” level. The “H” level output from the inverter INV3 is input to the gate of the transistor Tr3 and switches the transistor Tr3 to the ON state.

The transistor Tr1 enters the ON state upon input of the “L” level. The node N3 is electrically connected to the pad P1, so that the voltage of the node N3 makes a similar transition to the pad P1 and rises to the “H” level. Accordingly, the transistor Tr2 enters the ON state.

The resistor R1 and the capacitor C1 function as a trigger circuit which is triggered by the occurrence of the surge and sets the transistors Tr2 and Tr3 to the ON state. Since both the transistors Tr2 and Tr3 enter the ON state over the operation-in-surge-occurrence period, the on-state current Is flows from the pad P1 to the pad P2 along a current path passing through the transistors Tr2 and Tr3.

By operating as described above, the protection circuit 13 causes the on-state current Is to flow during the operation-in-surge-occurrence period and thereafter stops.

During the normal operation period, on the other hand, since the capacitor C1 is fully charged, the voltage of the node N1 reaches the voltage VDD. That is, the voltage of the node N1 rises to the “H” level.

When the voltage of the node N1 rises to the “H” level, the inverter INV1 outputs the “L” level. The “L” level output from the inverter INV1 is input to the inverter INV2. Then, the inverter INV2 outputs the “H” level to the node N2. Accordingly, the “H” level output from the inverter INV2 is input to the gate of the transistor Tr1 and to the input terminal of the inverter INV3.

The inverter INV3 outputs the “L” level upon input of the “H” level. The “L” level output from the inverter INV3 is input to the gate of the transistor Tr3 and sets the transistor Tr3 to the OFF state.

Further, the transistor Tr1 is in the OFF state upon input of the “H” level. Accordingly, the node N3 is electrically disconnected from the pad P1 but stays connected to the node N4 via the resistor R2. At this time, the voltage of the nodes N3 and N4 becomes voltage V1. The voltage V1 has the magnitude between the voltages VDD and VSS. The voltage V1 is, for example, lower than the voltage VT (the “L” level). In a case where the gate sizes of the transistors Tr2 and Tr3 are equivalent, the voltage V1 is, for example, about VDD/2. Thus, the transistor Tr2 is in the OFF state.

By operating as described above, the protection circuit 13 sets both of the transistors Tr2 and Tr3 to the OFF state, and thus, the on-state current Is does not flow during the normal operation period. The nodes N3 and N4 are maintained at the voltage V1.

### 1.3. Examples of Advantages of Present Embodiment

According to the first embodiment, a leak current, which flows in the protection circuit, can be reduced.

Examples of advantages of the first embodiment will be described below.

To prevent a surge, which occurs due to electrostatic discharge (ESD), from being applied to the internal circuit, a method of using an RC trigger MOS (RCTMOS) circuit for a protection circuit has been proposed.

The RCTMOS circuit is required to forcibly short-circuit a power supply terminal and a ground terminal when a surge occurs. Thus, a transistor having a large gate size is used in the RCTMOS circuit. Accordingly, a leak current which occurs in this transistor may increase depending on its gate size. Dominant factors of causing a leak current include, for example, a gate leak and a gate induced drain leakage (GIDL). The gate leak primarily occurs in accordance with a potential difference between the gate and drain of the transistor. The GIDL primarily occurs in accordance with a potential difference between the back gate and drain of the transistor and a potential difference between the gate and drain the transistor. Those types of leak currents are known to increase exponentially depending on a potential difference between the drain and source of the transistor.

According to the first embodiment, the transistor Tr1 includes a first terminal connected to the pad P1, the second terminal connected to the node N3, and the gate connected to the node N2. When the node N1 is at the “L” level, the voltage of the node N2 is at the “L” level. When the node N1 is at the “H” level, the voltage of the node N2 is at the “H” level. That is, the transistor Tr1 is set to the ON state due to the “L” level input to the gate of the transistor Tr1 when the node N1 is at the “L” level. The node N3 is electrically connected to the pad P1 during the operation-in-surge-occurrence period. Thus, since the “H” level is input to the gate of the transistor Tr2, the transistor Tr2 can be set to the ON state. On the other hand, the transistor Tr1 is in the OFF state due to the “H” level input to the gate of the transistor Tr1 when the node N1 is at the “H” level. Thus, the node N3 is electrically disconnected from the pad P1 during the normal operation period. Accordingly, since the “L” level is input to the gate of the transistor Tr2, the transistor Tr2 can be set to the OFF state.

Further, the resistor R2 electrically connects the nodes N3 and N4. Thereby, the voltage of the node N3 is maintained at the voltage of the node N4 during the normal operation period. Since the node N4 is an intermediate node between the transistors Tr2 and Tr3, the voltage of the nodes N3 and N4 is the voltage V1 that is an intermediate potential between the voltages VDD and VSS. Accordingly, the voltage of the gate and back gate of the transistor Tr2 can be set to the voltage V1.

Also, the inverter INV3 includes the input terminal connected to the node N2, and the output terminal connected to the gate of the transistor Tr3. The inverter INV3 outputs the “H” level when the node N1 is at the “L” level, and outputs the “L” level when the node N1 is at the “H” level. Accordingly, the transistor Tr3 can be set to the ON state during the operation-in-surge-occurrence period, and to the OFF state during the normal operation period.

Examples of advantages of the embodiment described above will be described in detail using a comparative example.

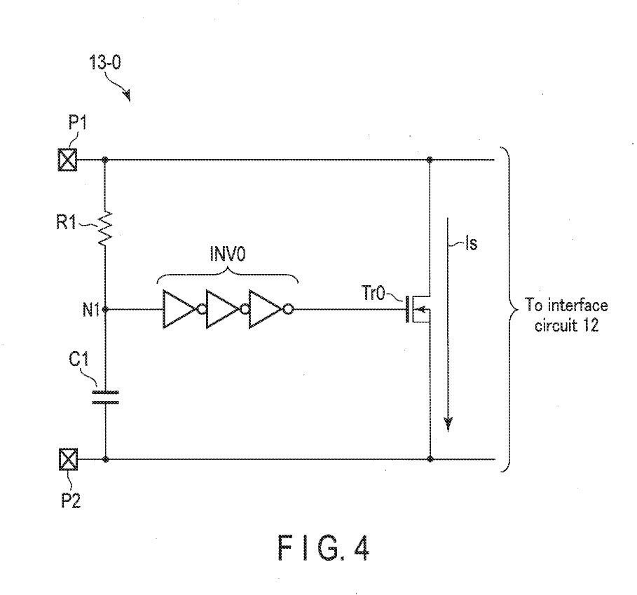

FIG. 4 is a circuit diagram for describing the configuration of a power supply protection circuit of a semiconductor device according to a comparative example. As shown in FIG. 4, the protection circuit 13-0 according to the comparative example includes the resistor R1, the capacitor C1, a plurality of inverters INV0 connected in series, and a transistor Tr0. The protection circuit 13-0 is analogous to the protection circuit 13 according to the first embodiment in which the transistors Tr1 and Tr2 and the resistor R2 are removed. More specifically, the transistor Tr0 includes a first terminal connected to the pad P1, a second terminal connected to the pad P2, and a gate connected to the output terminal of the plurality of inverters INV connected in series.

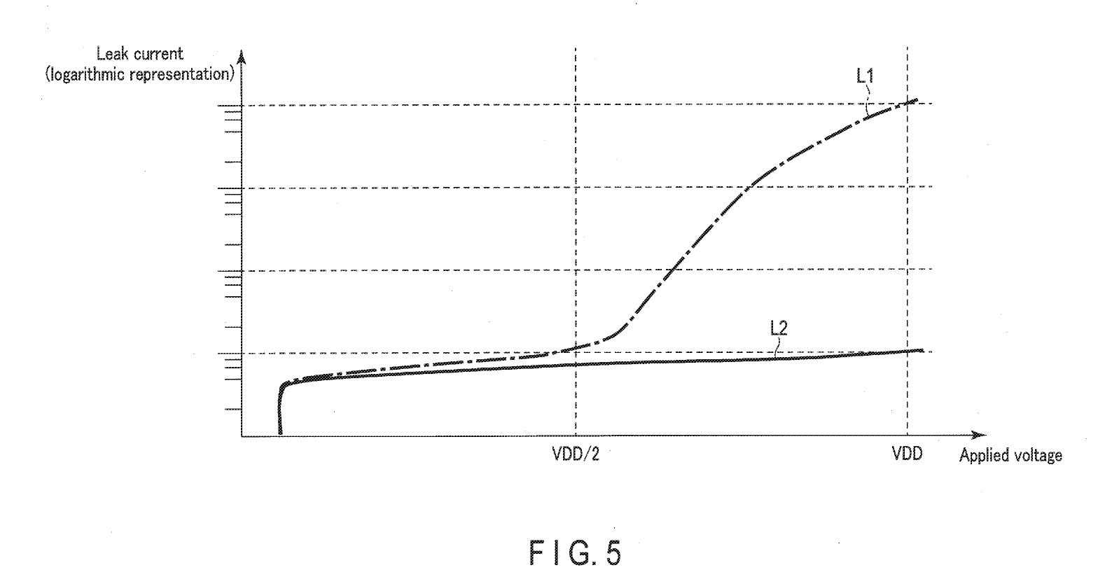

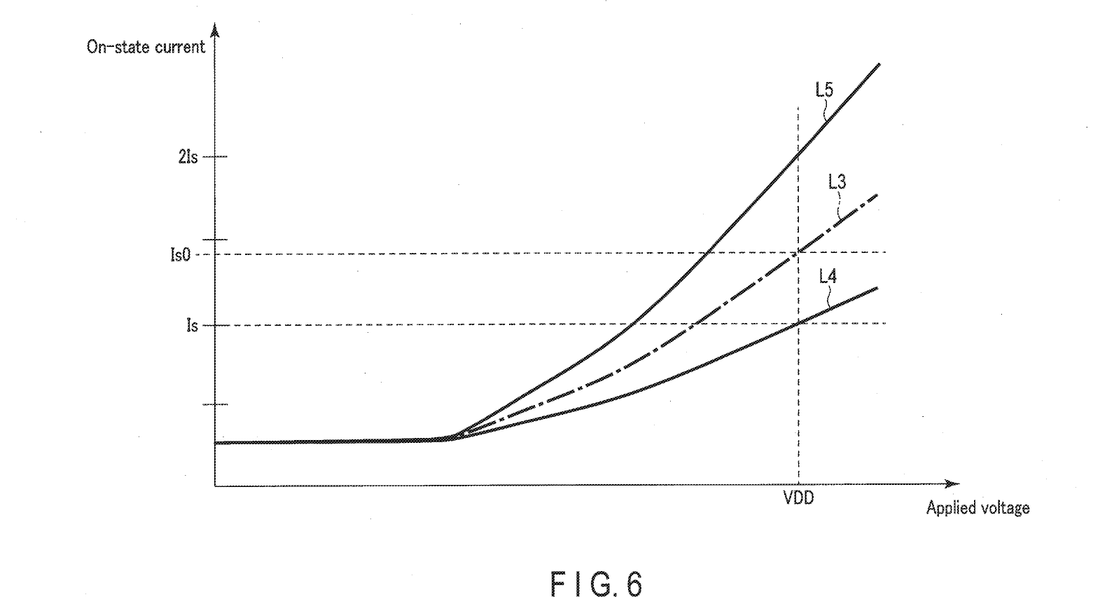

Referring to FIGS. 5 and 6, a description will be given of the comparison between the characteristics of the protection circuit 13-0 according to the above comparative example and the characteristics of the protection circuit 13 according to the first embodiment.

FIGS. 5 and 6 are diagrams for describing the advantage of the first embodiment. FIGS. 5 and 6 show the characteristics of the protection circuit 13 according to the first embodiment in comparison with the characteristics of the protection circuit 13-0 according to the comparative example.

First, one example of the advantages illustrated in FIG. 5 will be described. FIG. 5 logarithmically presents the magnitude of a leak current when the voltage VDD is normally applied to the pad P1 (the normal operation period). That is, FIG. 5 shows the magnitude of a leak current in a state where the on-state current Is, which is to short-circuit the pads P1 and P2, does not flow in the protection circuit. Specifically, in FIG. 5, a leak current of the protection circuit 13-0 is shown by curve line L1 (an alternate long and short dash line), whereas a leak current of the protection circuit 13 is shown by curve line L2 (a solid line).

As shown in FIG. 5, the leak current of the protection circuit 13 according to the first embodiment can be reduced lower than that of the protection circuit 13-0 according to the comparative example. Specifically, if a voltage to be supplied to the pad P1 is the voltage VDD, the protection circuit 13 can reduce the leak current to approximately one thousandth of that in the protection circuit 13-0. Further, when the voltage VDD is supplied, the leak current in the protection circuit 13 can be reduced to the same extent as the leak current generated in the protection circuit 13-0 when the voltage VDD/2 is supplied.

It is because in the normal operation period, in contrast with the protection circuit 13-0 in which a potential difference between the back gate and the drain of the transistor Tr0 and a potential difference between the gate and the drain of the transistor Tr0 are both equal to the voltage VDD, the protection circuit 13 according to the first embodiment has potential differences between the back gates and the drains of the transistors Tr2 and Tr3 and potential differences between the gates and the drains of the transistors Tr2 and Tr3 are both reduced to about the voltage VDD/2.

To be more specific, since the gate of the transistor Tr2 is connected to the node N3, a potential difference between the gate and the drain of the transistor Tr2 becomes nearly the voltage VDD/2. When the “L” level is output from the INV3, a potential difference between the gate of the transistor Tr3 and the node N4 becomes smaller than the voltage VDD/2. The potential differences between the gates and the drains of the transistors Tr2 and Tr3 are reduced, thereby reducing a leak current caused by a gate leak.

In addition, since the back gate of the transistor Tr2 is connected to the node N4, a potential difference between the back gate and drain of the transistor Tr2 becomes nearly the voltage VDD/2. Since the back gate of the transistor Tr3 is connected to the pad P2, a potential difference between the back gate of the transistor Tr3 and the node N4 becomes nearly the voltage VDD/2. Thus, the potential differences between the back gates and the drains of the transistors Tr2 and Tr3 are reduced, thereby reducing a leak current caused by gate-induced drain leakage (GIDL).

The protection circuit 13 according to the first embodiment is designed so that the transistors Tr2 and Tr3 have the same gate size. The voltage V1 is therefore equal to the voltage VDD/2. Accordingly, the potential differences between the back gates and the drains of the transistors Tr2 and Tr3 and the potential differences between the gates and the drains of the transistors Tr2 and Tr3 become the voltage VDD/2, and a leak voltage can be minimized.

Another example of the advantages shown in FIG. 6 will be described below. FIG. 6 assumes the operation to be performed when a surge occurs, and shows the magnitude of on-state currents Is corresponding to the voltage VDD supplied to the pad P1. Specifically, in FIG. 6, an on-state current of the protection circuit 13-0 is shown by curve line L3 (an alternate long and short dash line), whereas on-state currents of the protection circuit 13 are shown by curve lines L4 and L5 (solid lines). The curve line L4 shows a case where the transistors Tr2 and Tr3 adopt a gate size equivalent to that of the transistor Tr0. The curve line L5 shows a case where the transistors Tr2 and Tr3 adopt a gate size twice as large as that of the transistor Tr0.

As illustrated in FIG. 6, in the case where the transistors Tr2 and Tr3 have a gate of the same size as the transistor Tr0, the on-state current Is flowing in the protection circuit 13 is lower than the on-state current Is0 flowing in the protection circuit 13-0. This is because serial connection of the transistors Tr2 and Tr3 between the pads P1 and P2 virtually reduces the gate size of the transistors in the protection circuit 13. Thus, in the case where the transistors Tr2 and Tr3 have a gate of the same size as the transistor Tr0, the ESD protection characteristic of the protection circuit 13 is lower than that of the protection circuit 13-0.

In general, however, a correlation between the on-state current and the gate size exhibits linearity. Thus, as shown by the curve line L5, by making the size of the gate of the transistors Tr2 and Tr3 nearly double that of the transistor Tr0, for example, an on-state current Is equivalent to or an on-state current 2Is greater than the on-state current Is0 can be made to flow in the protection circuit 13.

In this regard, it is considered that a leak current increases linearly depending on an increase in a gate size. However, as illustrated in FIG. 5, the leak current in the protection circuit 13 is exponentially reduced (to approximately one thousandth) as compared to the leak current in the protection circuit 13-0. Thus, the power supply protection circuit 13 can sufficiently eliminate the impact by the increased gate size (increase by approximately double) that avoid a decrease in the ESD protection characteristic. Accordingly, the leak current can be reduced without deteriorating the ESD protection characteristic.

### 1.4 Modification of First Embodiment

It should be noted that the semiconductor device according to the first embodiment is not limited to the above example, and various modifications are applicable.

### 1.4.1 First Modification

According to one example, the protection circuit 13 may include a transistor in place of the transistor R2.

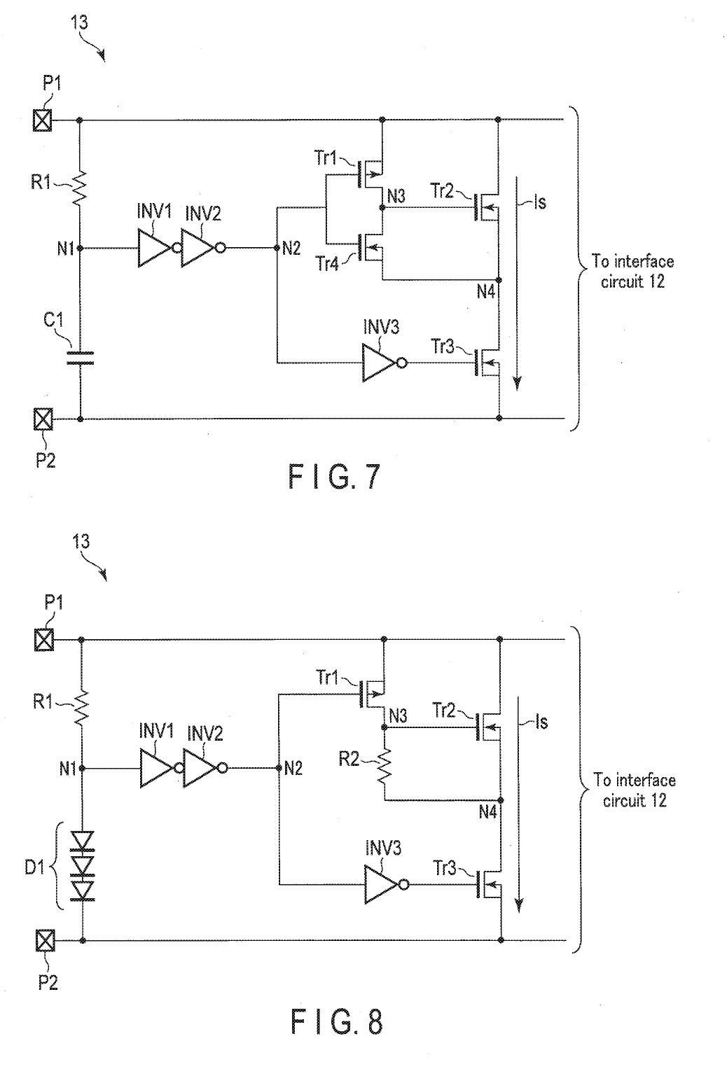

FIG. 7 is a circuit diagram for describing the configuration of a protection circuit according to a first modification of the first embodiment.

As illustrated in FIG. 7, a transistor Tr4 includes a first terminal connected to the node N3, a second terminal connected to the node N4, and a gate connected to the node N2. The transistor Tr4 has, for example, the n-channel polarity.

The transistor Tr4 is set to the OFF state in a case where the “L” level is supplied to the node N2, that is, in the operation-in-surge-occurrence period. Accordingly, the node N3 is electrically disconnected from the node N4, and the voltage to be supplied to the transistor Tr2 can be further stabilized. The transistor Tr4 is set to the ON state in a case where the “H” level is supplied to the node N2, that is, in the normal operation period. Accordingly, the node N3 can be electrically connected to the node N4 when the on-state current Is does not flow in the transistor Tr2. Thus, since a potential of the gate of the transistor Tr2 can be maintained at an intermediate potential V1 between potentials of the pads P1 and P2, the leak current is eventually reduced.

### 1.4.2 Second Modifications

The protection circuit 13 is not limited to the one having a trigger circuit with a timer function using an RC time constant. The power supply protection circuit 13 may include another trigger circuit without a timer function. FIGS. 8, 9, and 10 show circuit diagrams for describing the configuration of protection circuits according to second modifications of the first embodiment.

FIG. 8 shows an example in which the capacitor C1 is replaced with a plurality of diodes D1 connected in series. As illustrated in FIG. 8, the series of the plurality of diodes D1 includes an input terminal (anode) connected to the node N1, and an output terminal (cathode) connected to the pad P2. The diodes D1 are arranged to be in the ON state in a case where the voltage of the pad P1 rises to such an extent that the internal circuit 14 needs to be protected from ESD by flowing the on-state current Is.

By the above-described configuration, the voltage of the node N1 lowers to the “L” level due to a voltage drop across the resistor R1 when the series of diodes D1 is in the ON state. Accordingly, the transistors Tr2 and Tr3 are are set to the ON state, and the on-state current Is flows. When the voltage of the pad P1 returns to the normal operation range, the series of diodes D1 is in the OFF state. Accordingly, almost no voltage drop is produced across the resistor R1, and the voltage of the node N1 rises to the “H” level. Thus, the on-state current Is can be stopped.

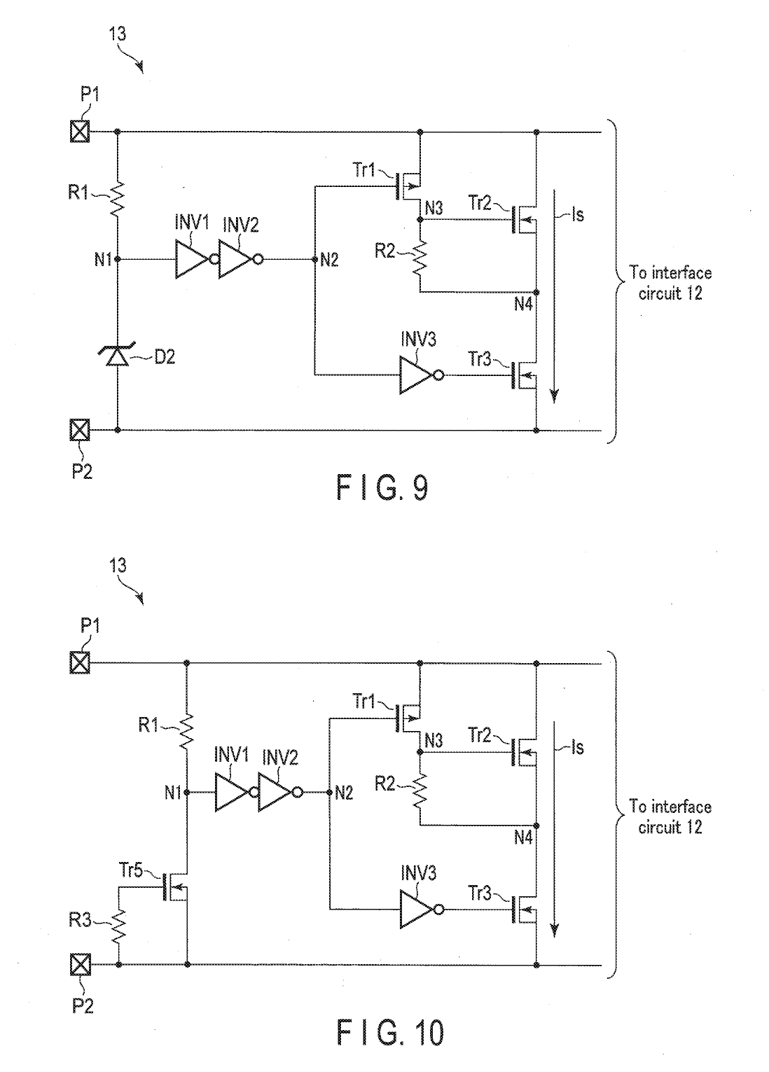

FIG. 9 shows an example in which the capacitor C1 is replaced with a Zener diode D2. As illustrated in FIG. 9, the Zener diode D2 includes an input terminal (cathode) connected to the node N1, and an output terminal (anode) connected to the pad P2. The Zener diode D2 is is arranged to be in the yield state when the voltage of the pad P1 rises to such an extent that the internal circuit 14 needs to be protected from ESD by flowing the on-state current Is.

By the above-described configuration, the voltage of the node N1 lowers to the “L” level due to a voltage drop across the resistor R1 when the Zener diode D2 is in the yield state. Thus, the transistors Tr2 and Tr3 are set to the ON state, and the on-state current Is can flow. When the voltage of the pad P1 returns to the normal operation range, the Zener diode D2 is reset from the yield state. Accordingly, almost no voltage drop is produced across the resistor R1, and the voltage of the node N1 rises to the “H” level. Thus, the on-state current Is can be stopped.

FIG. 10 shows an example in which the capacitor C1 is replaced with a transistor Tr5 and a resistor R3. As illustrated in FIG. 10, the transistor Tr5 includes a first terminal connected to the node N1, and a second terminal connected to the pad P2. The resistor R3 includes a first terminal connected to the gate of the transistor Tr5, and a second terminal connected to the pad P2. Like the Zener diode D2 shown in FIG. 9, the transistor Tr5 is arranged to be in the yield state in a case where the voltage of the pad P1 rises to such an extent that the internal circuit 14 needs to be protected from ESD by flowing the on-state current Is.

By the above-described configuration, the voltage of the node N1 lowers to the “L” level due to a voltage drop produced across the resistor R1 when the transistor Tr5 is in the yield state. Accordingly, the transistors Tr2 and Tr3 are set to the ON state, and the on-state current Is can flow. When the voltage of the pad P1 returns to the normal operation range, the transistor Tr5 is reset from the yield state. Accordingly, almost no voltage drop is produced across the resistor R1, and the voltage of the node N1 rises to the “H” level. Thus, the on-state current Is can be stopped.

### 1.4.3 Third Modification

In another example, the power supply protection circuit 13 may be configured to have an RC timer arranged in a direction opposite to the pads P1 and P2.

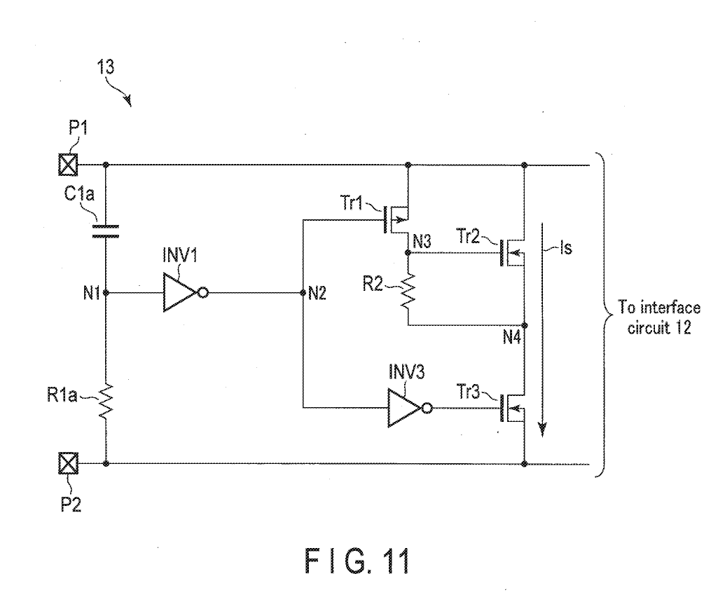

FIG. 11 is a circuit diagram for describing a protection circuit according to a third modification of the first embodiment. FIG. 11 shows an example in which the resistor R1 and the capacitor C1 are replaced with a capacitor C1a and a resistor R1a, respectively.

As illustrated in FIG. 11, the capacitor C1a includes a first terminal connected to the pad P1, and a second terminal connected to the node N1. The resistor R1a includes a first terminal connected to the node N1, and a second terminal connected to the pad P2. The resistor R1 and the capacitor C1 function as an RC timer that operates according to a time constant that is determined based on a resistance value of the resistor R1 and a capacitance of the capacitor C1.

In FIG. 11, the inverter INV2 is omitted. That is, the output terminal of the inverter INV1 is connected to the node N2.

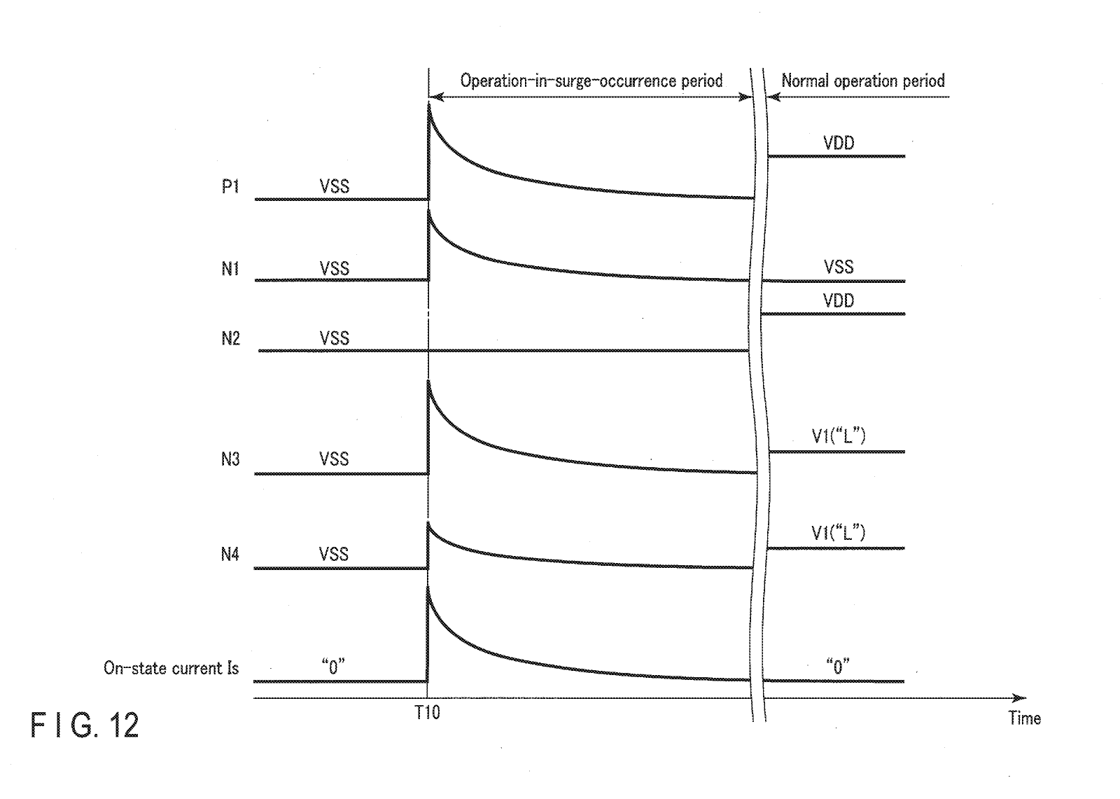

FIG. 12 is a timing chart showing the operation of the protection circuit according to the third modification of the first embodiment. FIG. 12 corresponds to FIG. 3 of the first embodiment.

As illustrated in FIG. 12, a surge occurs at time T10. Thus, the voltage of the pad P1 sharply rises and then gradually approaches the voltage VSS. The node N1 follows a voltage rise at the pad P1. Thus, the node N1 remains at the “H” level over the operation-in-surge-occurrence period. The inverter INV1 outputs the “L” level. Accordingly, the “L” level output from the inverter INV1 is input to the gate of the transistor Tr1 and to the input terminal of the inverter INV3 via the node N2.

Thus, due to both the transistors Tr2 and Tr3 entering the ON state, the on-state current Is flows from the pad P1 to the pad P2 along a current path passing through the transistors Tr2 and Tr3. Since the operations of the transistors Tr1 to Tr3 and the inverter INV3 are the same as in FIG. 3, a description thereof is omitted.

By the operations as described above, the protection circuit 13 causes the on-state current Is to flow during the operation-in-surge-occurrence period, and the flow stops thereafter.

On the other hand, during the normal operation period, the voltage of the node N1 becomes the voltage VSS. That is, the voltage of the node N1 lowers to the “L” level during the normal operation period. The inverter INV1 thus outputs the “H” level. Accordingly, the “H” level output from the inverter INV1 is input to the gate of the transistor Tr1 and to the input terminal of the inverter INV3.

Then, the transistors Tr2 and Tr3 are set to the OFF state, and the on-state current Is does not flow. Since the operations of the transistors Tr1 to Tr3 and the inverter INV3 are the same as in FIG. 3, a description thereof is omitted.

With the operations described above, the protection circuit 13 prevents the on-state current Is from flowing during the normal operation period. The voltages of the nodes N3 and N4 are maintained at the voltage V1.

As described above, even in the case where the RC timer is arranged in the opposite direction, the signals similar to those in the first embodiment can be input to the transistors Tr2 and Tr3. Therefore, this modification can provide the same advantages as in the first embodiment.

This modification is similarly applicable to the second modifications. That is, not only a trigger circuit with a timer function using an RC time constant, but also other trigger circuits without a timer function can be arranged in the opposite direction. Specifically, in FIG. 11 showing the third modification, the protection circuit 13 may be configured to have a plurality of diodes, a Zener diode, or a transistor in place of the capacitor C1a. The protection circuit 13 configured in this manner can also provide the same advantages as in the third modification.

### 2. Second Embodiment

Next, a semiconductor device according to a second embodiment will be described. The semiconductor device according to the first embodiment is configured to flow the on-state current Is via the transistors having an n-channel polarity. In contrast, the semiconductor device according to the second embodiment is different from that of the first embodiment in that the on-state current Is flows through transistors having a p-channel polarity. In the following, the same reference numerals and symbols as used in the first embodiment will be used for the same constituent elements, and detailed explanations thereof will be omitted. Only parts different from the first embodiment will be explained.

### 2.1 Configuration of Protection Circuit

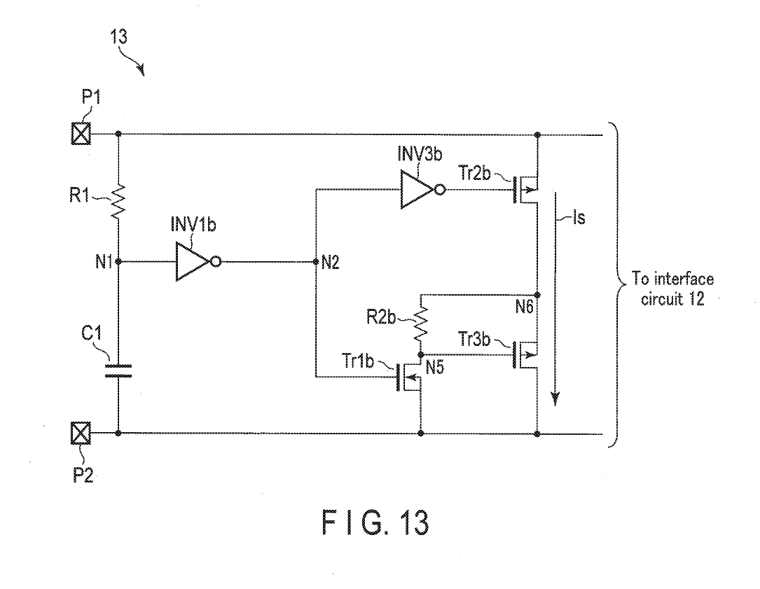

Referring to FIG. 13, an example of the protection circuit of the semiconductor device according to the second embodiment will be described. FIG. 13 corresponds to FIG. 2 showing the first embodiment.

As shown in FIG. 13, the protection circuit 13 includes transistors Tr1b, Tr2b, and Tr3b, resistors R1 and R2b, the capacitor C1, and inverters INV1b and INV3b. The transistor Tr1b has, for example, an n-channel polarity. The transistors Tr2b and Tr3b have, for example, a p-channel polarity. Since the configurations of the resistor R1 and the capacitor C1 are the same as those of FIG. 2 explained in the first embodiment, a description thereof will be omitted.

The inverter INV1b includes an input terminal connected to the node N1, and an output terminal connected to the node N2. The inverter INV3b includes an input terminal connected to the node N2, and an output terminal connected to a gate of the transistor Tr2b. The inverters INV1b and INV3b may be configured to output a signal of a value according to a potential difference between the pads P1 and P2.

The transistor Tr1b includes a first terminal and a back gate both connected to the pad P2, a second terminal connected to node N5, and a gate connected to the node N2. That is, the first terminal and the second terminal of the transistor Tr1b function as a source and a drain, respectively.

The resistor R2b includes a first terminal connected to the node N5, and a second terminal connected to node N6.

The transistor Tr2b includes a first terminal and a back gate both connected to the pad P1, a second terminal connected to the node N6, and a gate connected to the output terminal of the inverter INV3b. The transistor Tr3b includes a first terminal and a back gate both connected to the node N6, a second terminal connected to the pad P2, and a gate connected to the node N5. That is, the first terminals of the transistors Tr2b and Tr3b function as a source, whereas the second terminals of the transistors Tr2b and Tr3b function as a drain. It is preferable that the transistors Tr2b and Tr3b have approximately the same gate size.

It is preferable that the transistors Tr1b to Tr3b are switched to the ON state or to the OFF state, for example, at a certain voltage (to be referred to as “voltage VTb” for the purpose of convenience) between the voltage VDD and the voltage VSS. It is more preferable that the voltage VTb is set between the voltage VDD/2 and the voltage VSS. The transistor Tr1b is in the ON state when a voltage higher than the voltage VTb is applied to the gate of the transistor Tr1b, and in the OFF state when a voltage lower than the voltage VTb is applied to the gate of the transistor Tr1b. The transistors Tr2b and Tr3b are in the OFF state when a voltage higher than the voltage VTb is applied to the gates of the transistors Tr2b and Tr3b, and in the ON state when a voltage lower than the voltage VTb is applied to the gates of the transistors Tr2b and Tr3b. Thus, regarding the transistors with the p-channel polarity and the transistor with the n-channel polarity, it is preferable that when the former are in the ON state, the latter is in the OFF state, and when the former are in the OFF state, the latter is in the ON state.

In the description below, in regard to voltages which are applied to the gates of the transistors Tr1b to Tr3b, a logic level of a voltage lower than the voltage VTb is referred to as the “L” level, and a logic level of a voltage higher than the voltage VTb is referred to as the “H” level.

Like the transistors Tr1b to Tr3b, the inverters INV1b and INV3b may be configured to switch signals output from the output terminals depending on voltage values of signals input to the input terminals with reference to the voltage VTb. To be more specific, each of the inverters INV1b and INV3b may output the “H” level from the output terminal when the “L” level is input to the input terminal, and output the “L” level from the output terminal when the “H” level is input to the input terminal.

### 2.2 Operation of Protection Circuit

Next, the operations of the protection circuit of the semiconductor device according to the second embodiment will be described.

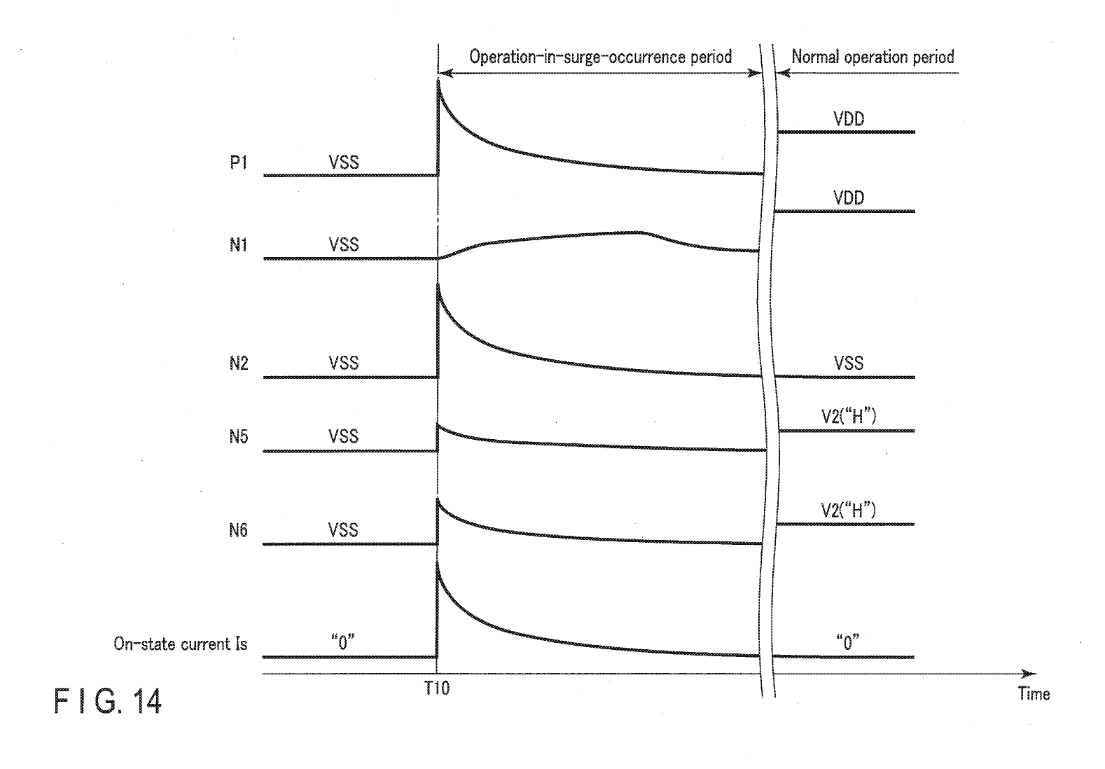

FIG. 14 is a timing chart for describing the operations of the protection circuit according to the second embodiment. FIG. 14 shows, as one example, the operations of the protection circuit 13 when a surge occurs and when a power supply is normally supplied.

As shown in FIG. 14, since the operations up to time T10 are the same as in the first embodiment, a description thereof will be omitted.

A surge occurs at time T10, thereby causing the voltage of the pad P1 to sharply rise and then gradually approach the voltage VSS. The voltage of the node N1 gradually increases, as an electric charge is accumulated in the capacitor C1 due to the surge. However, the voltage of the node N1 decreases again following the decrease in the voltage of the pad P1. Thus, the node N1 remains at the “L” level over the operation-in-surge-occurrence period.

Then, the inverter INV1b outputs the “H” level to the node N2. Accordingly, the “H” level output from the inverter INV1b is input to the gate of the transistor Tr1b and to the input terminal of the inverter INV3b.

The inverter INV3b outputs the “L” level upon input of the “H” level. The “L” level output from the inverter INV3b is input to the gate of the transistor Tr2b and sets the transistor Tr2b to the OFF state.

Further, the transistor Tr1b enters the ON state upon input of the “H” level. Since the node N5 is electrically connected to the node N6 and the pad P2, the voltage of the node N5 follows a variation of the voltage of the node N6. However, the voltage of the node N5 has the magnitude between the voltages VSS and VDD, and this magnitude is sufficient to cause the transistor Tr3b to be in the ON state. That is, the voltage of the node N5 is set to the “L” level.

As described above, since both the transistors Tr2b and Tr3b are in the ON state over the operation-in-surge-occurrence period, the on-state current flows from the pad P1 to the pad P2 along a current path passing through the transistors Tr2b and Tr3b.

During the normal operation period, on the other hand, as the capacitor C1 is fully charged, the voltage of the node N1 reaches the voltage VDD. That is, the node N1 is set to the “H” level.

When the voltage of the node N1 is at the “H” level, the inverter INV1b outputs the “L” level. Accordingly, the “L” level output from the inverter INV1b is input to the gate of the transistor Tr1b and to the input terminal of the inverter INV3b.

The inverter INV3b outputs the “H” level upon input of the “L” level. The “H” level output from the inverter INV3b is input to the gate of the transistor Tr2b and sets the transistor Tr2b to the OFF state.

The transistor Tr1b enters the OFF state upon input of the “L” level, and the node N5 is electrically disconnected from the pad P2, but stays connected to the node N6 via the resistor R2b. At this time, the voltage of the nodes N5 and N6 becomes voltage V2. The voltage V2 has the magnitude between the voltages VDD and VSS. The voltage V2 is, for example, higher than the voltage VTb (“H” level). In a case where the transistors Tr2b and Tr3b are equivalent in gate size, for example, the voltage V2 is about VDD/2. Accordingly, the transistor Tr3b is set to the OFF state.

With the operations as described above, since the protection circuit 13 sets both of the transistors Tr2b and Tr3b to the OFF state during the normal operation period, the on-state current Is does not flow. In addition, the voltage of the nodes N5 and N6 is maintained at the voltage V2.

### 2.3 Advantages of Second Embodiment

According to the second embodiment, the transistor Tr1b includes the first terminal connected to the pad P2, the second terminal connected to the node N5, and the gate connected to the node N2. When the node N1 is at the “L” level, the voltage of the node N2 is at the “H” level. When the node N1 is at the “H” level, the voltage of the node N2 is at the “L” level. That is, when the node N1 is at the “L” level, the transistor Tr1b is set to the ON state upon input of the “H” level to the gate of the transistor Tr1b. Thus, the node N5 is electrically connected to the pad P2 during the operation-in-surge-occurrence period. Accordingly, since the “L” level is input to the gate of the transistor Tr3b, the transistor Tr3b can be set to the ON state. On the other hand, when the node N1 is at the “H” level, the transistor Tr1b is in the OFF state upon input of the “L” level to the gate of the transistor Tr1b. Then, the node N5 is electrically disconnected from the pad P2 during the normal operation period. Accordingly, since the “H” level is input to the gate of the transistor Tr3b, the transistor Tr3b can be set to the OFF state.

The resistor R2b electrically connects the nodes N5 and N6. The voltage of the node N5 is maintained at the voltage of the node N6 during the normal operation period. Since the node N6 is an intermediate node between the transistors Tr2b and Tr3b, the voltage of the node N6 becomes the voltage V2 as an intermediate potential between the voltages VDD and VSS. Accordingly, the voltages of the gate and back gate of the transistor Tr3b can be set to the voltage V2.

The inverter INV3b includes the input terminal connected to the node N2, and the output terminal connected to the gate of the transistor Tr2b. The inverter INV3b outputs the “L” level when the node N1 is at the “L” level, and outputs the “H” level when the node N1 is at the “H” level. Accordingly, the transistor Tr2b can be in the ON state during the operation-in-surge-occurrence period, and can be in the OFF state during the normal operation period.

Therefore, even in the case where the transistors Tr2b and Tr3b of the p-channel polarity flow the on-state current Is according to the second embodiment, the transistors Tr2b and Tr3b can be operated in the same manner as in the first embodiment. Therefore, the second embodiment can provide the same advantages as the first embodiment.

### 2.4 Modification of Second Embodiment

A semiconductor device according to the second embodiment is not limited to the above example, and various modifications are applicable.

### 2.4.1 First Modification

The protection circuit 13, for example, may include a transistor in place of the resistor R2b.

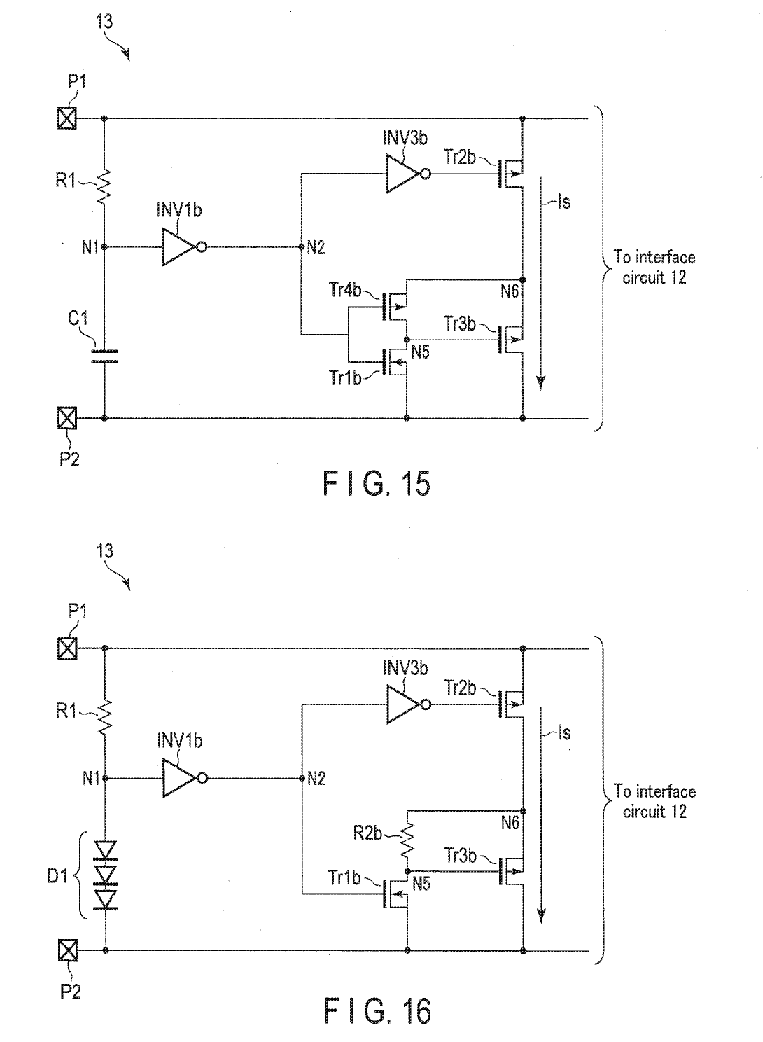

FIG. 15 is a circuit diagram for describing the configuration of a protection circuit of the semiconductor device according to a first modification of the second embodiment.

As illustrated in FIG. 15, a transistor Tr4b includes a first terminal connected to the node N5, a second terminal connected to the node N6, and a gate connected to the node N2. The transistor Tr4b has, for example, a p-channel polarity.

The transistor Tr4b is in the OFF state in a case where the “H” level is supplied to the node N2, that is, in the operation-in-surge-occurrence period. Accordingly, the node N5 is electrically disconnected from the node N6, and the voltage to be supplied to the transistor Tr3b can be further stabilized. The transistor Tr4b is in the ON state in a case where the “L” level is supplied to the node N2, that is, in the normal operation period. Accordingly, the node N5 can be electrically connected to the node N6 when the on-state current Is does not flow through the transistor Tr3b. Thus, the potential of the transistor Tr3b can be maintained at the intermediate potential V2 between the pads P1 and P2, and as a result, the leak current is reduced.

### 2.4.2 Second Modifications

The protection circuit 13 is not limited to the one having a trigger circuit with a timer function using an RC time constant. The protection circuit 13 may include other trigger circuits without a timer function. FIGS. 16, 17, and 18 are circuit diagrams for describing power supply protection circuits according to second modifications of the second embodiment.

FIG. 16 shows an example in which the capacitor C1 is replaced with a plurality of diodes D1 connected in series. As illustrated in FIG. 16, the series of the plurality of diodes D1 includes an input terminal (anode) connected to the node N1, and an output terminal (cathode) connected to the pad P2. The series of the plurality of diodes D1 is arranged to be in the ON state in a case where the voltage of the pad P1 rises to such an extent that the internal circuit 14 needs to be protected from ESD by flowing the on-state current Is.

With the configuration described above, the voltage of the node N1 is at the “L” level due to a voltage drop across the resistor R1 when the series of the diodes D1 is in the ON state. Accordingly, since the transistors Tr2b and Tr3b are set to the ON state, the on-state current Is can flow. When the voltage of the pad P1 returns to the normal operation range, the series of diodes D1 are set to the OFF state. Thus, almost no voltage drop is produced across the resistor R1, and the voltage of the node N1 is at the “H” level. Then, the on-state current Is can be stopped.

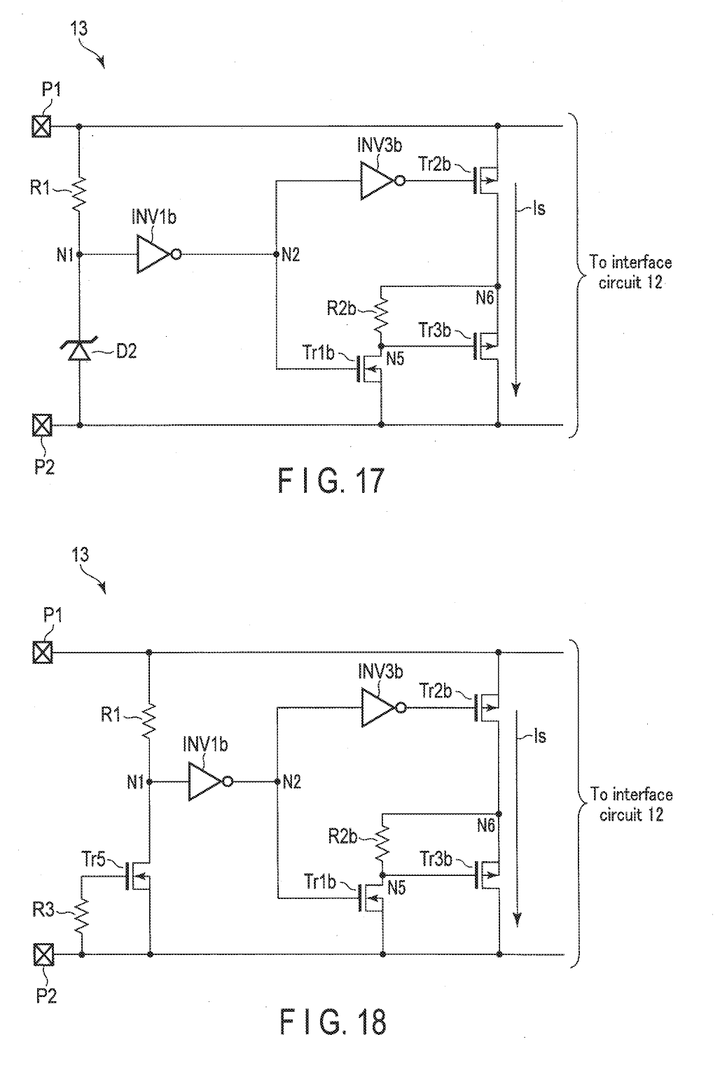

FIG. 17 shows an example in which the capacitor C1 is replaced with a Zener diode D2. As illustrated in FIG. 17, the Zener diode D2 includes an input terminal (cathode) connected to the node N1, and an output terminal (anode) connected to the pad P2. The Zener diode D2 is arranged to be in the yield state in a case where the voltage of the pad P1 rises to such an extent that the internal circuit 14 needs to be protected from ESD by flowing the on-state current Is.

With the configuration described above, the voltage of the node N1 lowers to the “L” level due to a voltage drop across the resistor R1 when the Zener diode D2 is in the yield state. Then, since the transistors Tr2b and Tr3b are set to the ON state, the on-state current Is can flow. When the voltage of the pad P1 returns to the normal operation range, the Zener diode D2 is reset from the yield state. Accordingly, almost no voltage drop is produced across the resistor R1, and the voltage of the node N1 is at the “H” level. Thus, the on-state current Is can be stopped.

FIG. 18 shows an example in which the capacitor C1 is replaced with a transistor Tr5 and a resistor R3. As illustrated in FIG. 18, the transistor Tr5 includes a first terminal connected to the node N1, and a second terminal connected to the pad P2. The resistor R3 includes a first terminal connected to the gate of the transistor Tr5, and a second terminal connected to the pad P2. Like the Zener diode D2 shown in FIG. 17, the transistor Tr5 is arranged to be in the yield state in a case where the voltage of the pad P1 rises to such an extent that the internal circuit 14 needs to be protected from ESD by flowing the on-state current Is.

With the configuration described above, the voltage of the node N1 lowers to the “L” level due to a voltage drop across the resistor R1 when the transistor Tr5 is in the yield state. This switches the transistors Tr2b and Tr3b to the ON state, and the on-state current Is flows. When the voltage of the pad P1 returns to the normal operation range, the transistor Tr5 is reset from the yield state. Accordingly, almost no voltage drop is produced across the resistor R1, and the voltage of the node N1 is at the “H” level. Then, the on-state current Is can be stopped.

### 2.4.3 Third Modification

The power supply protection circuit 13, for example, may include an RC timer arranged in a direction opposite to the pads P1 and P2.

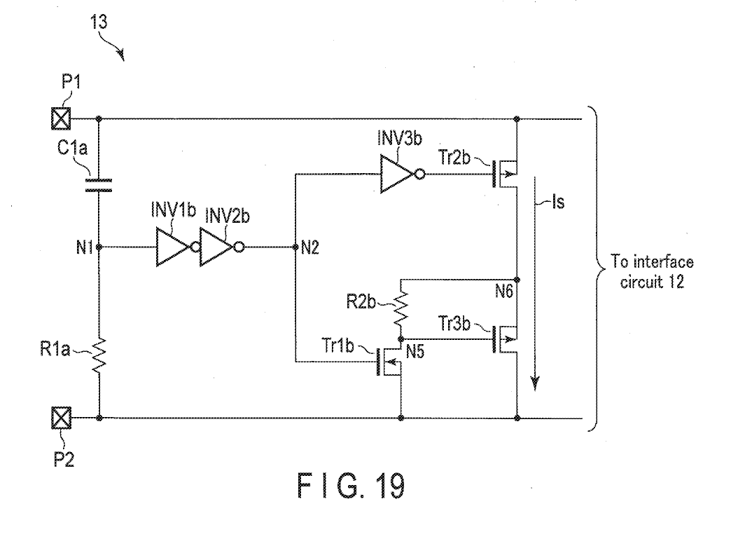

FIG. 19 is a circuit diagram for describing the configuration of a protection circuit of a semiconductor device according to a third modification of the second embodiment. FIG. 19 shows an example of the protection circuits which includes a capacitor C1a and a resistor R1a in place of the resistor R1 and the capacitor C1, respectively.

As illustrated in FIG. 19, the capacitor C1a includes a first terminal connected to the pad P1, and a second terminal connected to the node N1. The resistor R1a includes a first terminal connected to the node N1, and a second terminal connected to the pad P2. The resistor R1 and the capacitor C1a function as an RC timer which operates according to a time constants determined based on a resistance value of the resistor R1 and a capacitance of the capacitor C1. Specifically, the voltage of the node N1 follows a voltage of the pad P2 with a time delay based on the aforementioned time constant.

According to the third modification of the second embodiment, the protection circuit 13 further includes an inverter INV2b. The inverter INV2b includes an input terminal that is connected to the output terminal of the inverter INV1b and an output terminal that is connected to the node N2.

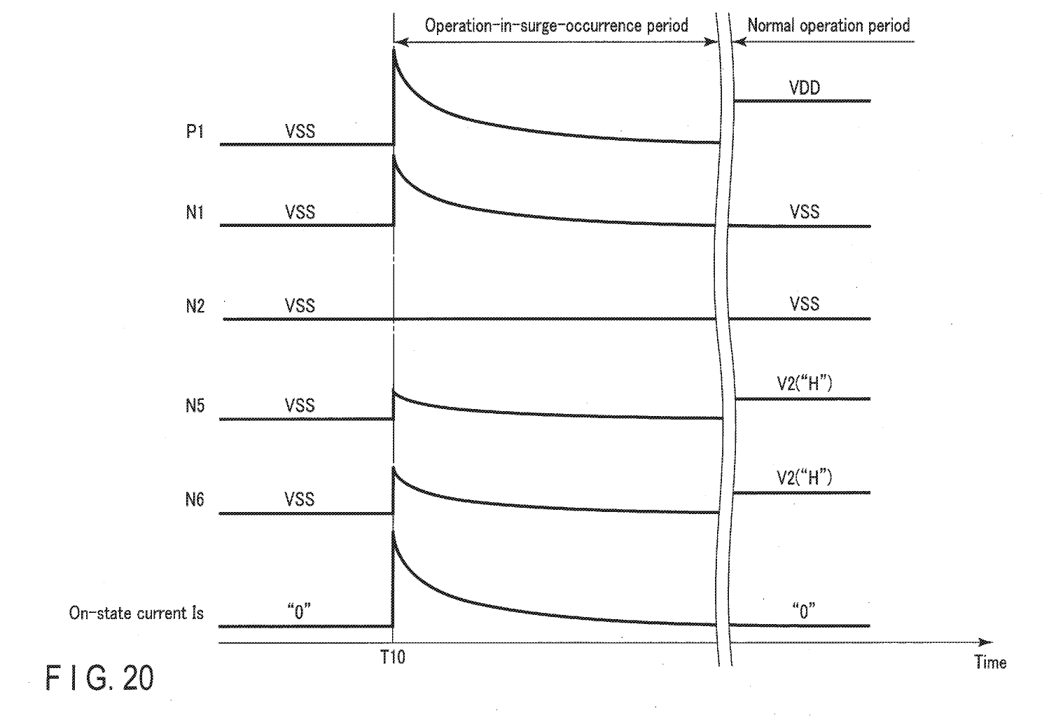

FIG. 20 is a circuit diagram showing the operation of the power supply protection circuit according to the third modification of the second embodiment.

As illustrated in FIG. 20, a surge occurs at time T10. Thus, the voltage of the pad P1 sharply rises and then gradually approaches the voltage VSS. The node N1 follows a voltage rise at the pad P1. The node N1 remains at the “H” level over the operation-in-surge-occurrence period. Then, the inverter INV1b outputs the “L” level, whereas the inverter INV2b outputs the “H” level. The “H” level output from the inverter INV2b is input to the gate of the transistor Tr1b and to the input terminal of the inverter INV3b.

Accordingly, since both the transistors Tr2b and Tr3b are in the ON state, the on-state current Is flows from the pad P1 to the pad P2 along a current path passing through the transistors Tr2b and Tr3b. Since the operations of the transistors Tr1b to Tr3b and the inverter INV3b are the same as in FIG. 14 explained in the second embodiment, a description thereof is omitted.

With the operations as described above, the protection circuit 13 causes the on-state current Is to flow during the operation-in-surge-occurrence period, and the on-state current Is stops thereafter.

During the normal operation period, the voltage of the node N1 is the voltage VSS. That is, during the normal operation period, the voltage of the node N1 is at the “L” level. The inverter INV1b outputs the “H” level, whereas the inverter INV2b outputs the “L” level. The “L” level output from the inverter INV2b is input to the gate of the transistor Tr1b and to the input terminal of the inverter INV3b.

The transistors Tr2b and Tr3b are thus in the OFF state, and the on-state current Is does not flow. Since the operations of the transistors Tr1b to Tr3b and the inverter INV3b are the same as in FIG. 14 explained in the second embodiment, a description thereof is omitted.

With the operations as described above, the protection circuit 13 prevents the on-state current Is from flowing during the normal operation period. In addition, the nodes N5 and N6 are maintained at the voltage V2.

Thus, even in the case where the RC timer is arranged in the opposite direction, the signals similar to those in the second embodiment can be input to the transistors Tr2b and Tr3b. Therefore, this modification can provide the same advantages as the second embodiment.

This modification is applicable to the second modifications, in a similar manner. That is, not only a trigger circuit with a timer function using an RC time constant, but also other trigger circuits without a timer can be arranged in the opposite direction. Specifically, in FIG. 19 showing the third modification, the protection circuit 13 may be configured to include a series of a plurality of diodes, a Zener diode, and a transistor, in place of the capacitor C1a. The protection circuits 13 so configured can also provide the same advantages as in the third modification.

### 5. Others

In addition, the following aspects are applicable to each embodiment and each modification.

Described in the above are the examples in which the inverters are serially connected in three stages to the transistor Tr3 according to the first embodiment, and to the transistor Tr2b according to the third modification of the second embodiment. However, the embodiments and modifications are not limited to these examples. For example, inverters serially connected in given odd-numbered stages can be connected to the transistor Tr3 according to the first embodiment, and to the transistor Tr2b according to the third modification of the second embodiment.

Described in the above are examples in which inverters in two stages are serially connected to the transistor Tr3 according to the third modification of the first embodiment, and to the transistor Tr2b according to the second embodiment. However, the embodiments and modifications are not limited to these examples. For example, inverters serially connected in given even-numbered stages can be connected to the transistor Tr3 according to the third modification of the first embodiment, and to the transistor Tr2b according to the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the circuits, methods and systems described herein may be made without departing from the spirit of the inventions. The accompanying claims and their equivalents are intended to cover such forms or modifications as would fall within the scope and spirit of the invention.

What is claimed is:

1. A protection circuit of a semiconductor device, comprising:
a first pad to which a first voltage is supplied;
a second pad to which a second voltage different from the first voltage is supplied;
a first transistor including:
a first terminal that is electrically connected to the first pad;
a second terminal and a back gate that are electrically connected to a first node; and
a gate that is electrically connected to a second node;
a second transistor including:
a first terminal that is electrically connected to the first node;
a second terminal and a back gate that are electrically connected to the second pad; and
a gate; and
a switch circuit configured to:
electrically connect the second node to the first pad in a case where a first logic signal is input to the gate of the second transistor; and
electrically disconnect the second node from the first pad and electrically connect the second node to the first node in a case where a second logic signal whose logic level is opposite to a logic level of the first logic signal is input to the gate of the second transistor.

2. The circuit of claim 1, wherein the first transistor and the second transistor are identical in polarity.

3. The circuit of claim 2, wherein
the switch circuit includes a third transistor,
the third transistor includes:
a first terminal that is electrically connected to the first pad; and
a second terminal that is electrically connected to the second node, and
the third transistor is different in polarity from the first transistor and the second transistor.

4. The circuit of claim 3, wherein a logic signal whose logic level is opposite to a logic level of the first logic signal to be input to the gate of the second transistor is input to a gate of the third transistor.

5. The circuit of claim 4, wherein
the switch circuit further includes a first resistor, and
the first resistor includes:
a first terminal that is electrically connected to the first node; and
a second terminal that is electrically connected to the second node.

6. The circuit of claim 4, wherein
the switch circuit further includes a fourth transistor, and
the fourth transistor includes:
a first terminal that is electrically connected to the first node;
a second terminal that is electrically connected to the second node; and
a gate that is electrically connected to the gate of the third transistor.

7. The circuit of claim 6, wherein the fourth transistor is different in polarity from the third transistor.

8. The circuit of claim 1, wherein the first voltage is greater than the second voltage.

9. The circuit of claim 1, wherein the first voltage is smaller than the second voltage.

10. The circuit of claim 3, further comprising:
a trigger circuit that is electrically connected between the first pad and the second pad, and outputs a trigger signal to a third node; and
a signal control circuit that switches a logic level of a logic signal to be input to the gate of the second transistor and to the gate of the third transistor, depending on whether a voltage value of the trigger signal exceeds a threshold.

11. The circuit of claim 10, wherein the trigger circuit includes:
a second resistor including:
a first terminal that is electrically connected to the first pad; and
a second terminal that is electrically connected to the third node; and
a capacitor including:
a first terminal that is electrically connected to the third node; and
a second terminal that is electrically connected to the second pad.

12. The circuit of claim 10, wherein the trigger circuit includes:
a second resistor including:
a first terminal that is electrically connected to the first pad; and
a second terminal that is electrically connected to the third node; and
a fifth transistor including:
a first terminal that is electrically connected to the third node; and
a second terminal and a gate that are electrically connected to the second pad.

13. The circuit of claim 10, wherein the trigger circuit includes:
a second resistor including:
a first terminal that is electrically connected to the first pad; and
a second terminal that is electrically connected to the third node; and
a diode including:
a first terminal that is electrically connected to the third node; and
a second terminal that is electrically connected to the second pad.

14. The circuit of claim 13, wherein the diode includes a Zener diode.

15. The circuit of claim 10, wherein the trigger circuit includes:
a capacitor including:
a first terminal that is electrically connected to the first pad; and
a second terminal that is electrically connected to the third node; and
a second resistor including:
a first terminal that is electrically connected to the third node; and
a second terminal that is electrically connected to the second pad.

16. The circuit of claim 10, wherein the trigger circuit includes:
a fourth transistor including:
a first terminal and a gate that are electrically connected to the first pad; and
a second terminal that is electrically connected to the third node; and
a second resistor including:
a first terminal that is electrically connected to the third node; and
a second terminal that is electrically connected to the second pad.

17. The circuit of claim 10, wherein the trigger circuit includes:
a diode including:
a first terminal that is electrically connected to the first pad; and
a second terminal that is electrically connected to the third node; and
a second resistor including:
a first terminal that is electrically connected to the third node; and
a second terminal that is electrically connected to the second pad.

18. The circuit of claim 17, wherein the diode includes a Zener diode.
